(19) United States
(12) Patent Application Publication
(10) Pub. No.: US 2010/0055843 A1
(43) Pub. Date: Mar. 4, 2010

(54) CHIP PACKAGE MODULE HEAT SINK

(75) Inventor: Chien-Hung Liu, Taoyuan Hsien (TW)

Correspondence Address: LIU & LIU, 444 S. FLOWER STREET SUITE 1750, LOS ANGELES, CA, 90071, US

(73) Assignee: XINTEC, INC., Taoyuan Hsien (TW)

(21) Appl. No.: 12/615,159

(22) Filed: Nov. 9, 2009

Related U.S. Application Data
(62) Division of application No. 11/653,425, filed on Jan. 16, 2007.

(51) Int. Cl. H01L 21/00

(52) U.S. Cl. 438/122; 257/E21.001

(57) ABSTRACT

A heat sink mechanism including multiple heat passages in the base of a casing of a chip package module penetrating through a substrate packed in the module; a metal material being deposited in each heat passage to become a heat sink conductor connecting the substrate and the surface of the casing to effectively solve the problem of excessive heat generated in the course of HF operation of the chip package module thus to prevent chip failure.

### BACKGROUND OF THE INVENTION

(a) Field of the Invention

The present invention is related to a chip package module heat sink mechanism, and more particularly to a method and associate construction by improving the package structure to effectively solve the overheated package module due to HF (high frequency) operation for preventing chip failure.

(b) Description of the Prior Art

Whereas compact construction is demanded for electronic products, assembly and construction technologies for electronic devices also head for becoming lighter, thinner, shorter, and smaller. Chips or multi-chip electronic devices generally available in the market for transmission of I/O (input/output) signals and electric currents, and providing heat sink to protect chip, they must be integrated into a chip package module through package process.

As illustrated in FIG. 1 of the accompanying drawings, a typical chip package module A of an image sensor is essentially comprised of two portions including a casing 10 of mechanical configuration and a circuit configuration. Wherein, a base of the casing 10 is comprised of an insulation layer 14, a metallic conduction layer 15, and a masking layer 16 soldered to the outermost; and a top of the casing 10 is comprised of a transparent device 19. The circuit configuration includes a substrate 12 and multiple circuit pins 13, and multiple photo sensor chips 11 are arranged on a surface of the substrate 12 in the casing 10.

The insulation layer 14, the metallic conduction layer 15, and the outmost masking layer 16 are outwardly disposed in sequence on the other surface of the substrate 12. The metallic conduction layer 15 is electrically connected to those photo sensor chips 11 arranged on top of the substrate 12. Those multiple circuit pins 13 are disposed on the masking layer 16 to connect the metallic conduction layer 15 with each pin 13 formed with a ball in the masking layer 16 to facilitate a process of surface adhesion by soldering. In the construction of the chip package module A of the prior art, the insulation layer 14, the metallic conduction layer 15, and the outmost masking layer 16 constitute a base of the casing 10 while the transparent device 19 covering over those photo sensor chips 11 constitute the top of the casing 10.

Chip package module A of the prior art and other similar modules to the prior art are each essentially comprised of the substrate 12. Taking the field use of an image sensor for example, though the substrate 12 provides a certain extent of heat dissipation, those photo sensor chips 11 are vulnerable to fail when overheated. The overheat is resulted from excessive change of amperage when the entire chip package module A is processing fast changed images and the heat generated by those photo sensor chips 11 fails to be dissipated through the substrate 12, the insulation layer 14 and the masking layer 16 in sequence since the entire substrate 12 is fully packed by the masking layer 16 and the insulation layer 14, both are given lower heat conduction coefficients.

### SUMMARY OF THE INVENTION

The primary purpose of the present invention is to provide a heat sink mechanism that is effective to solve the problem of chip failure when overheated as a result of HF operation of a chip package module.

To achieve the purpose, multiple heat passages penetrating through the base are disposed in the base of a casing of the chip package module, and a metallic material is provided in each heat passage by means is of deposition as a heat sink conductor connecting the substrate and the surface of the casing to prevent chip failure by dissipating the heat generated during HF operation of the chip package module.

### BRIEF DESCRIPTION OF THE DRAWINGS

FIG. 1 is a sectional view of a photo sensor chip package module for an image sensor of the prior art.

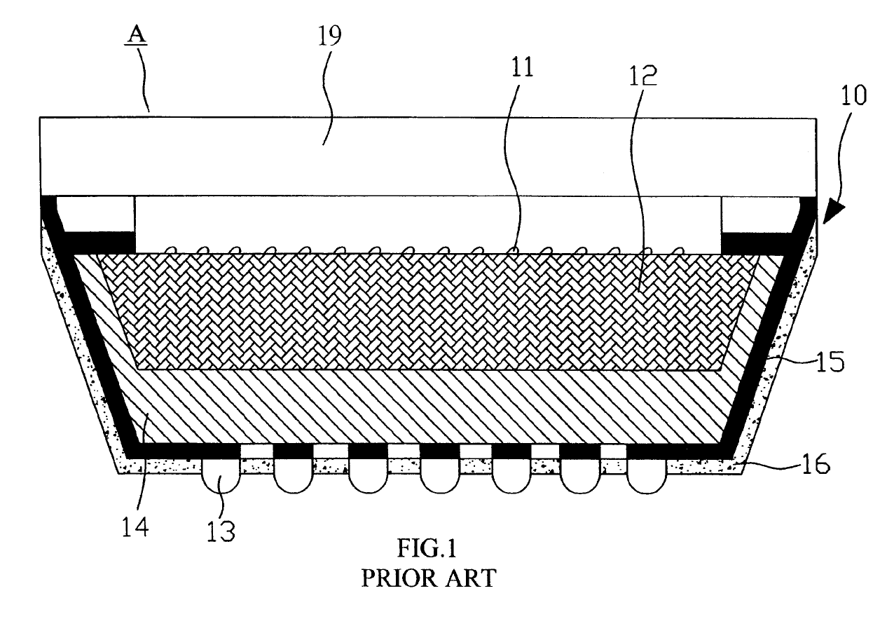

FIG. 2 is a sectional view showing a construction of a chip package module of a first preferred embodiment of the present invention.

FIG. 3 is a sectional view showing a construction of a chip package module of a second preferred embodiment of the present invention.

FIG. 4 is a sectional view showing a construction of a chip package module of a third preferred embodiment of the present invention.

FIG. 5 is a sectional view showing a construction of a chip package module of a fifth preferred embodiment of the present invention.

### DETAILED DESCRIPTION OF THE PREFERRED EMBODIMENTS

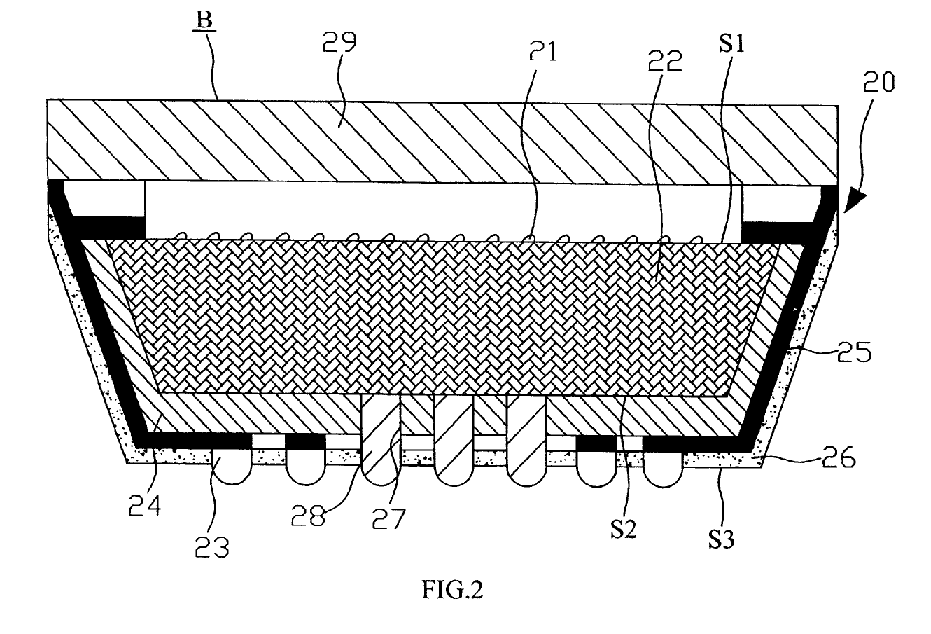

A heat sink mechanism of the present invention is related to one adapted to a chip package module to effective correct the problem of overheated chip due to HF operation of the chip package module thus to prevent chip failure. As illustrated in FIG. 2, a chip package module B, similar to that of a prior art, includes a casing 20 in a mechanical configuration with its base comprised of an insulation layer 24, a metallic conduction layer 25, and an outmost masking layer 26 soldered to the base; a top of the casing 20 is comprised of a transparent device 29; a circuit configuration including a substrate 22 and multiple pins 23; and multiple photo sensor chips 21 arranged on a surface of the substrate 22 in the casing 20. Wherein, the substrate 22 may be made of silicon or any other proper materials and the transparent device 29 is made of acrylic, polyester, glass or any other transparent material.

Those photo sensor chips 21 are constructed on a first surface S1 of the substrate 22, and the top of the casing 20 is related to the transparent device 29 located at where above those photo sensor chips 21. A second surface S2 in opposite to the first surface S1 of the substrate 22 is outwardly constructed with the insulation layer 24, the metallic conduction layer 25, and the masking layer 26. The base of the casing 20 is comprised of the insulation layer 24, the metallic conduction layer 25, and the masking layer 26. The metallic conduction layer 25 is electrically connected to those photo sensor chips 21 located over the substrate 22; and multiple pins 23 connecting to the metallic conduction layer 25 are disposed on the masking layer 26.

The heat sink mechanism is essentially comprised of multiple heat passages 27 disposed in the base of the casing 20 of the chip package module B and penetrating through the substrate 22 to contact the second surface S2 of the substrate 22. A heat sink conductor 28 is disposed in each heat passage 27. The conductor 28 is related to a metal, graphite, metal oxide, or a polymer containing metal, graphite, or metal oxide material provided in the heat passage by means of deposition to connect the substrate 22 and a surface S3 of the casing 20. Accordingly, with the heat conduction executed by the heat sink conductor 28, the heat generated from heat source inside the chip package module is conducted to the casing 20 and released into ambient air so to effectively dissipate excessive heat generated from HF operation of the chip package module and further to prevent failure of the photo sensor chip.

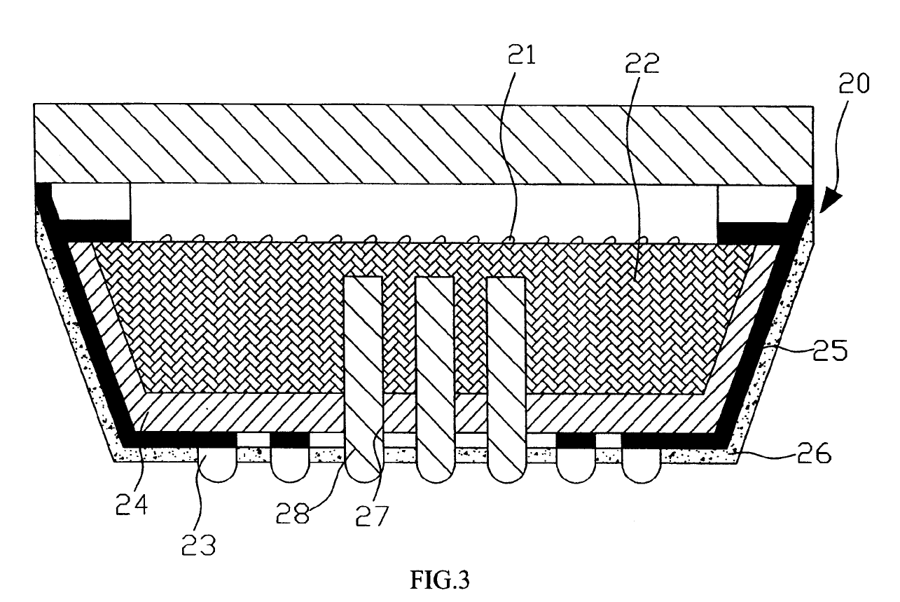

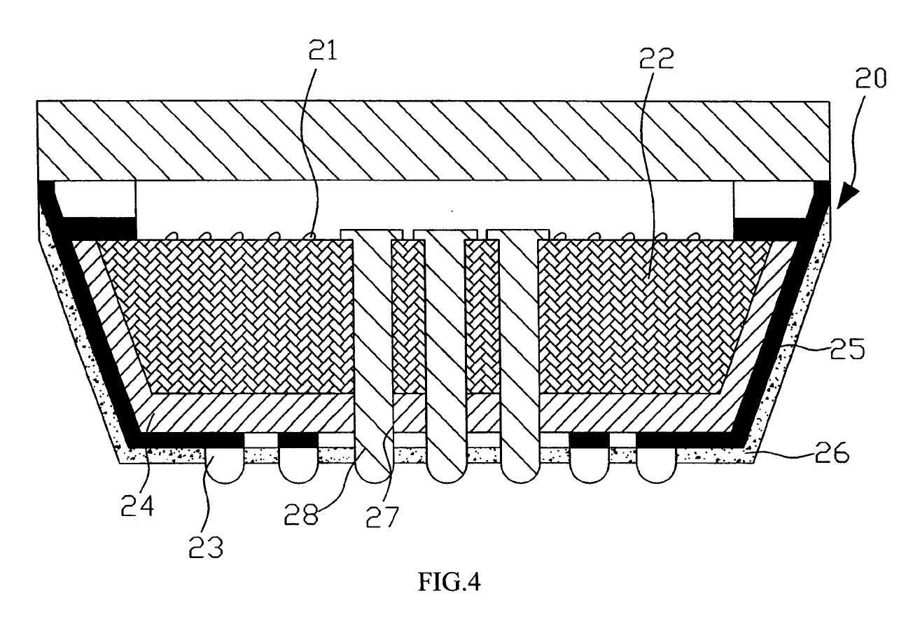

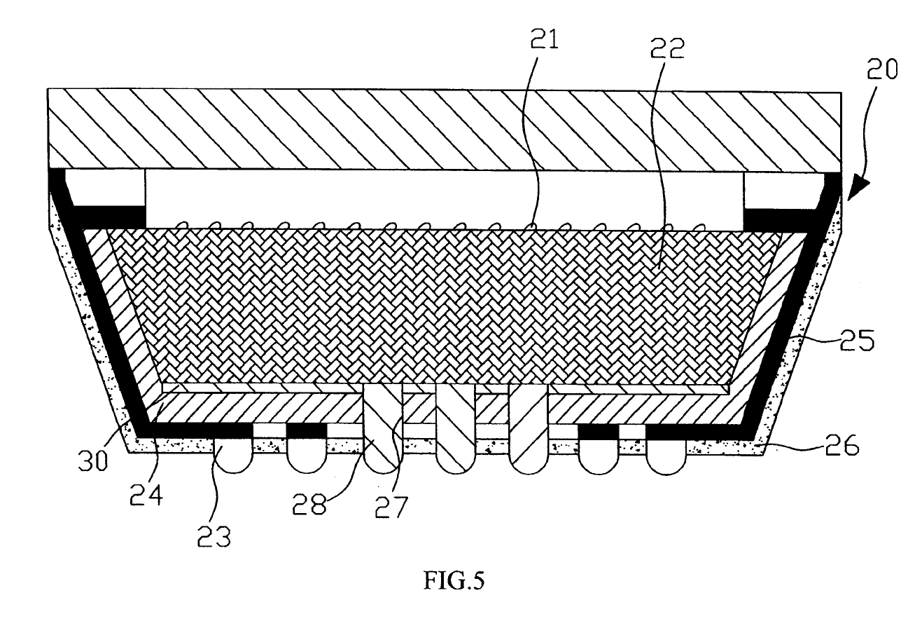

In practice, a spherical 3D (three dimensions) configuration of each heat sink conductor 28 is formed on the surface S3 of the casing to further upgrade heat dissipation. The contact mode between the heat sink conductor 28 and the substrate 22 may be such that as illustrated in FIG. 2, wherein the heat is transmitted to the exterior of the casing 20 by direct contacting the second surface S2 of the substrate 22; or the heat sink conductor 28 is provided deeper into the substrate 22 as illustrated in FIG. 3; or the heat sink conductor 28 penetrates through the first surface S1 of the substrate 22 as illustrated in FIG. 4; or an accommodation space 30 is provided between the casing 20 and the second surface S2 of the substrate 22 for the deposited metal to diffuse to the second surface S2 of the substrate 22 as illustrated in FIG. 5 for each heat sink conductor 28 to connect to the second surface S2 of the substrate 22 for increasing the contact area between the heat sink conductor 28 and the substrate 22 for facilitating heat dissipation efficiency.

The prevent invention provides a heat sink mechanism adapted to a chip package module, and the application for a patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

1-20. (canceled)

21. A method of fabricating a chip package module comprising:
providing a semiconductor substrate made of silicon material;
attaching at least one chip to the semiconductor substrate;
forming an insulation layer to cover a bottom surface of the semiconductor substrate;
forming heat passages through the insulation layer and at least a portion of the semiconductor substrate; and
forming heat metal conductors with metal protrusions in the heat passages by means of deposition, wherein the metal protrusions are located under the heat metal conductors and outside a bottom surface of the insulation layer.

22. The method of claim 21, further comprising disposing the semiconductor substrate and the chip within a non-wire bonding package.
